(19) United States
(12) Patent Application Publication
(10) Pub. No.: US 2025/0267991 A1
(43) Pub. Date: Aug. 21, 2025

(54) DISPLAY DEVICE

(71) Applicant: LG Display Co., Ltd., Seoul (KR)

(72) Inventors: Sungmoo KIM, Goyang-si (KR); Heumeil BAEK, Seoul (KR); DAE-IL KANG, Gimpo-si (KR); Soojin KIM, Incheon (KR)

(73) Assignee: LG Display Co., Ltd., Seoul (KR)

(21) Appl. No.: 18/939,245

(22) Filed: Nov. 6, 2024

(30) Foreign Application Priority Data
Feb. 16, 2024 (KR) 10-2024-0022497

(51) Int. Cl. H01L 33/58; H01L 25/16

(52) U.S. Cl. CPC H10H 20/855; H01L 25/167

(57) ABSTRACT

A display device can include a first substrate on which a plurality of subpixels is defined, a plurality of blue light-emitting elements respectively disposed on the plurality of subpixels, a plurality of color conversion layers, a plurality of color filters, a second substrate, and a first transmittance adjustment layer disposed below the second substrate and configured to surround the plurality of color filters. The first transmittance adjustment layer includes a first layer disposed below the second substrate, and a second layer disposed below the first layer of the first transmittance adjustment layer. The second layer of the first transmittance adjustment layer has a lower transmittance than the first layer of the first transmittance adjustment layer. Therefore, it is possible to improve color properties.

### CROSS-REFERENCE TO RELATED APPLICATIONS

This application claims priority to Korean Patent Application No. 10-2024-0022497 filed on Feb. 16, 2024, in the Korean Intellectual Property Office, the entire contents of which is hereby expressly incorporated by reference into the present application.

### FIELD

The present disclosure relates to a display device, and more particularly, to a display device capable of improving color properties.

### DISCUSSION OF THE RELATED ART

As display devices used for a monitor of a computer, a TV set, a mobile phone, and the like, there are an organic light-emitting display (OLED) configured to autonomously emit light, and a liquid crystal display (LCD) that requires a separate light source.

The range of application of the display devices can be diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED can be quickly turned on or off, have excellent luminous efficiency, high impact resistance, and great stability, and display high-brightness images.

### SUMMARY OF THE DISCLOSURE

An object to be achieved by the present disclosure is to provide a display device capable of improving luminance and color properties.

Another object to be achieved by the present disclosure is to provide a display device capable of minimizing a decrease in efficiency of blue light.

Objects of the present disclosure are not limited to the above-mentioned objects, and other objects, which are not mentioned above, can be clearly understood by those skilled in the art from the following descriptions.

A display device according to an embodiment of the present disclosure can include a first substrate on which a plurality of subpixels is defined, a plurality of blue light-emitting elements respectively disposed on the plurality of subpixels, a plurality of color conversion layers disposed on the plurality of blue light-emitting elements in a red subpixel and a green subpixel among the plurality of subpixels, a plurality of color filters disposed on the plurality of color conversion layers in the red subpixel and the green subpixel, a second substrate disposed on the plurality of color filters, and a first transmittance adjustment layer disposed below the second substrate and configured to surround the plurality of color filters, in which the first transmittance adjustment layer includes a first layer disposed below the second substrate, and a second layer disposed below the first layer of the first transmittance adjustment layer and having a lower transmittance than the first layer of the first transmittance adjustment layer.

Other detailed matters of the example embodiments of the present disclosure are included in the detailed description and the drawings.

According to aspects of the present disclosure, the banks can be disposed at two stages while corresponding to the plurality of pixels, thereby improving luminance and color properties.

According to aspects of the present disclosure, it is possible to minimize a color deviation in accordance with a viewing angle.

According to aspects of the present disclosure, blue light is emitted in an intact manner, which can minimize a decrease in light emission efficiency.

The effects according to aspects of the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic top plan view of a display device according to an embodiment of the present disclosure;

FIG. 2 is a top plan view illustrating a part of the display area according to the embodiment of the present disclosure;

FIG. 3 is a cross-sectional view taken along line III-III′ in FIG. 2;

FIG. 4 is a cross-sectional view taken along line IV-IV′ in FIG. 2;

FIG. 5 is a graph illustrating viewing angles for respective subpixels of the display device according to a comparative example;

FIG. 6 is an enlarged cross-sectional view illustrating a green subpixel and a red subpixel of a display device according to another embodiment of the present disclosure; and

FIG. 7 is an enlarged cross-sectional view illustrating a blue subpixel of the display device according to another embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure. Further, the term “can” fully encompasses all the meanings and coverages of the term “may.”

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various example embodiments of the present disclosure will be described in detail with reference to the accompanying drawings. All the components of each display device according to all embodiments of the present disclosure are operatively coupled and configured.

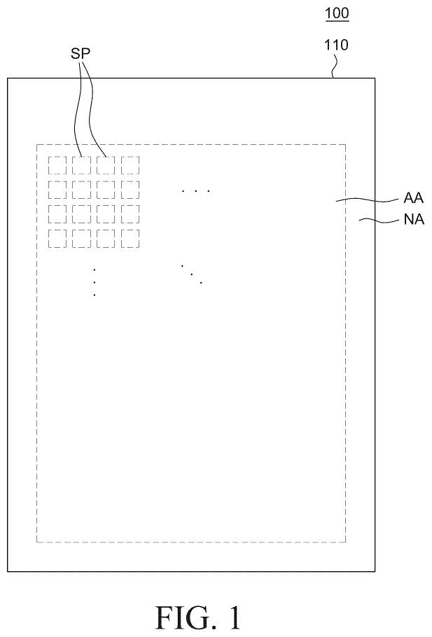

FIG. 1 is a schematic configuration view of a display device according to an embodiment of the present disclosure, and illustrates a schematic top plan view of the display device according to the embodiment of the present disclosure. For convenience of description, FIG. 1 illustrates a first substrate 110 and a plurality of subpixels SP among various constituent elements of a display device 100.

Referring to FIG. 1, the first substrate 110 is a component for supporting various constituent elements included in the display device 100 and can be made of an insulating material. For example, the first substrate 110 can be made of glass, resin, or the like. In addition, the first substrate 110 can include plastic such as polymer and can be made of a material having flexibility.

The first substrate 110 includes a display area AA (or active area) and a non-display area NA (or non-active area). The non-display area NA can surround the display area AA entirely or only in part(s).

The display area AA is an area in which the plurality of subpixels SP is disposed to display images. A display element, a drive circuit for operating the display element, and the like can be disposed in each of the plurality of subpixels SP in the display area AA. For example, an LED, a transistor for operating the LED, and the like can be disposed in each of the plurality of subpixels SP.

The non-display area NA is an area in which no image is displayed. Various lines, drive ICs (Integrated Circuits), and the like for operating the subpixels SP disposed in the display area AA are disposed. For example, various drive ICs, such as a gate driver IC and a data driver IC, and various drive circuits can be disposed in the non-display area NA. Meanwhile, the non-display area NA can be positioned on a rear surface of the first substrate 110, i.e., a surface on which the subpixel SP is not present. Alternatively, the non-display area NA can be excluded. However, the present disclosure is not limited to the configuration illustrated in the drawings.

The plurality of subpixels SP is defined in the display area AA of the first substrate 110. The plurality of subpixels SP is each an individual unit configured to emit light. A light-emitting element and a driving element are formed on each of the plurality of subpixels SP. For example, the plurality of subpixels SP can include a red subpixel, a green subpixel, a blue subpixel, and/or a white subpixel. However, the present disclosure is not limited thereto. Hereinafter, for convenience of description, the description will be made on the assumption that the plurality of subpixels SP includes the red subpixel, the green subpixel, and the blue subpixel. However, other variations (e.g., including a white subpixel) are possible and part of the present disclosure.

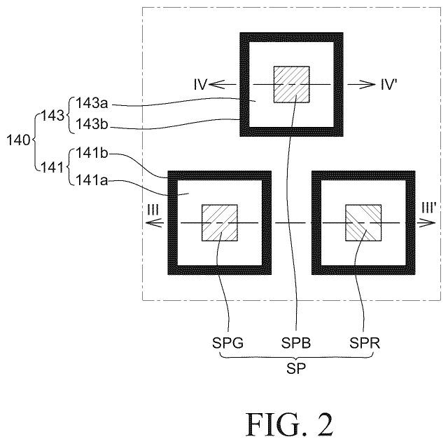

Hereinafter, the display area AA of the display device 100 will be described in more detail with reference to FIGS. 2 to 4.

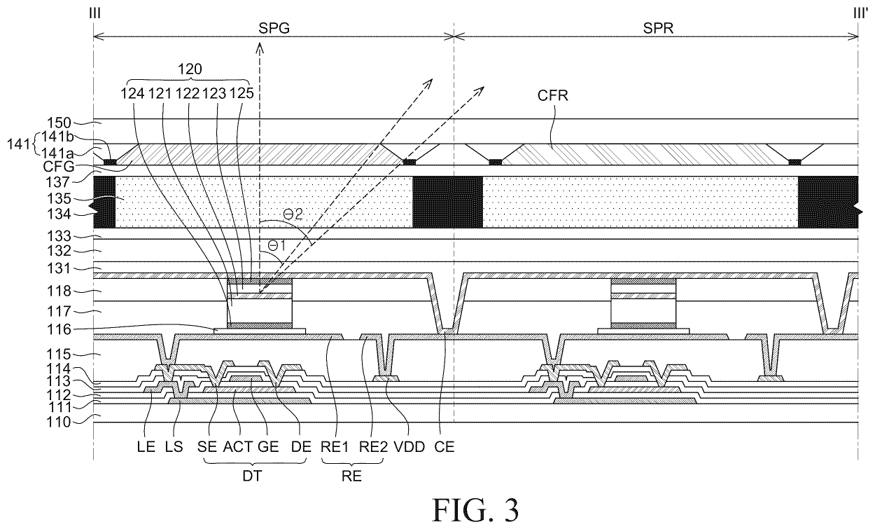

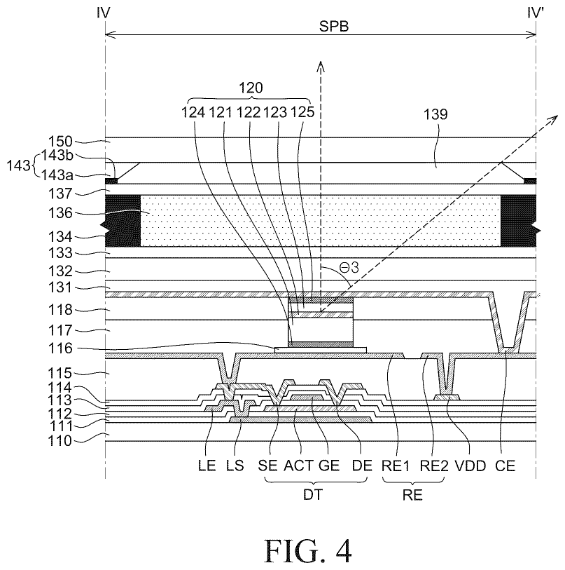

FIG. 2 is a top plan view illustrating a part of the display area according to the embodiment of the present disclosure, and FIG. 3 is a cross-sectional view taken along line III-III′ in FIG. 2. FIG. 4 is a cross-sectional view taken along line IV-IV′ in FIG. 2. Meanwhile, for convenience of illustration, FIG. 2 illustrates the plurality of subpixels SP and a transmittance adjustment layer 140 among various constituent elements of the display device 100.

First, with reference to FIG. 2, the display area AA includes the plurality of subpixels SP, each of the plurality of subpixels SP is an individual unit configured to emit light, and the light-emitting element is disposed in each of the plurality of subpixels SP. The plurality of subpixels SP includes a red subpixel SPR, a green subpixel SPG, and a blue subpixel SPB that emit light beams with different colors. For example, the colors of the light beams implemented by the plurality of subpixels SP and the configuration and arrangement of the plurality of subpixels SP can vary in accordance with design. However, the present disclosure is not limited thereto.

With reference to FIGS. 3 and 4, the first substrate 110, a buffer layer 111, a gate insulation layer 112, a first interlayer insulation layer 113, a second interlayer insulation layer 114, an overcoating layer 115, a conductive bonding layer 116, a first planarization layer 117, a second planarization layer 118, a driving transistor DT, a light-emitting element 120, a plurality of reflective electrodes RE, a light-blocking layer LS, an auxiliary electrode LE, a connection electrode CE, a third planarization layer 131, a bonding layer 132, an encapsulation layer 133, a bank 134, a color conversion layer 135, a first transparent layer 136, a second transparent layer 139, a plurality of color filters CFG and CFR, the transmittance adjustment layer 140, and a second substrate 150 are disposed in each of the plurality of subpixels SP of the display panel of the display device 100 according to the embodiment of the present disclosure.

First, the first substrate 110 can be configured to support various constituent elements included in the display device 100 and made of an insulating material. For example, the first substrate 110 can be made of glass, resin, or the like. In addition, the first substrate 110 can include plastic such as polymer and can be made of a material having flexibility.

The light-blocking layer LS is disposed in each of the plurality of subpixels SP on the first substrate 110. The light-blocking layer LS blocks light entering an active layer ACT of the driving transistor DT, which will be described below, from a lower side of the first substrate 110. The light-blocking layer LS can block light entering the active layer ACT of the driving transistor DT, thereby minimizing a leakage current.

The buffer layer 111 is disposed on the first substrate 110 and the light-blocking layer LS. The buffer layer 111 can reduce the penetration of moisture or impurities through the first substrate 110. For example, the buffer layer 111 can be configured as a single layer or multilayer made of silicon oxide (SiOx) or silicon nitride (SiNx). However, the present disclosure is not limited thereto. However, the buffer layer 111 can be excluded in accordance with the type of first substrate 110 or the type of transistor. However, the present disclosure is not limited thereto.

The driving transistor DT is disposed on the buffer layer 111. The driving transistor DT includes the active layer ACT, a gate electrode GE, a source electrode SE, and a drain electrode DE.

The active layer ACT is disposed on the buffer layer 111. The active layer ACT can be made of a semiconductor material such as an oxide semiconductor, amorphous silicon, or polysilicon. However, the present disclosure is not limited thereto.

The gate insulation layer 112 is disposed on the active layer ACT. The gate insulation layer 112 is an insulation layer for insulating the active layer ACT and the gate electrode GE. The gate insulation layer 112 can be configured as a single layer or multilayer made of silicon oxide (SiOx) or silicon nitride (SiNx). However, the present disclosure is not limited thereto.

The gate electrode GE is disposed on the gate insulation layer 112. The gate electrode GE can be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first interlayer insulation layer 113 and the second interlayer insulation layer 114 are disposed on the gate electrode GE. Contact holes, through which the source electrode SE and the drain electrode DE are connected to the active layer ACT, are formed in the first interlayer insulation layer 113 and the second interlayer insulation layer 114. The first interlayer insulation layer 113 and the second interlayer insulation layer 114 can be insulation layers for protecting components disposed below the first interlayer insulation layer 113 and components disposed below the second interlayer insulation layer 114 and each configured as a single layer or multilayer made of silicon oxide (SiOx) or silicon nitride (SiNx). However, the present disclosure is not limited thereto.

The source electrode SE and the drain electrode DE are disposed on the second interlayer insulation layer 114 and electrically connected to the active layer ACT. The source electrode SE and the drain electrode DE can each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Meanwhile, in the present disclosure, the configuration has been described in which the first interlayer insulation layer 113 and the second interlayer insulation layer 114, i.e., the plurality of insulation layers is disposed between the gate electrode GE, the source electrode SE, and the drain electrode DE. However, only a single insulation layer can be disposed between the gate electrode GE, the source electrode SE, and the drain electrode DE. However, the present disclosure is not limited thereto.

Further, as illustrated in the drawings, in case that the plurality of insulation layers, such as the first interlayer insulation layer 113 and the second interlayer insulation layer 114, is disposed between the gate electrode GE, the source electrode SE, and the drain electrode DE, an electrode can be additionally formed between the first interlayer insulation layer 113 and the second interlayer insulation layer 114. The additionally formed electrode can define a capacitor together with other components disposed on the lower portion of the first interlayer insulation layer 113 or the upper portion of the second interlayer insulation layer 114.

The auxiliary electrode LE is disposed on the gate insulation layer 112. The auxiliary electrode LE is an electrode that electrically connects the light-blocking layer LS, which is disposed below the buffer layer 111, to any one of the source electrode SE and the drain electrode DE on the second interlayer insulation layer 114. For example, the light-blocking layer LS can be electrically connected to any one of the source electrode SE or the drain electrode DE through the auxiliary electrode LE so as not to be operated as a floating gate, thereby minimizing a change in threshold voltage of the driving transistor DT caused by the floating light-blocking layer LS. The drawing illustrates that the light-blocking layer LS is connected to the source electrode SE. However, the light-blocking layer LS can be connected to the drain electrode DE. However, the present disclosure is not limited thereto.

A power line VDD is disposed on the second interlayer insulation layer 114. The power line VDD can be electrically connected to the light-emitting element 120 together with the driving transistor DT and allow the light-emitting element 120 to emit light. The power line VDD can be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The overcoating layer 115 is disposed on the driving transistor DT and the power line VDD. The overcoating layer 115 can planarize an upper portion of the first substrate 110 on which the driving transistor DT is disposed. The overcoating layer 115 can be configured as a single layer or multilayer and made of a photoresist or an acrylic-based organic material, for example. However, the present disclosure is not limited thereto. The plurality of reflective electrodes RE, which is spaced apart from one another, is disposed on the overcoating layer 115. The plurality of reflective electrodes RE can serve to electrically connect the light-emitting element 120 to the power line VDD and the driving transistor DT and serve as a reflective plate that reflects light, which is emitted from the light-emitting element 120, to an upper portion of the light-emitting element 120. The plurality of reflective electrodes RE can each be made of an electrically conductive material having excellent reflection performance and reflect the light, which is emitted from the light-emitting element 120, toward the upper portion of the light-emitting element 120.

The plurality of reflective electrodes RE includes a first reflective electrode RE1 and a second reflective electrode RE2. The first reflective electrode RE1 can electrically connect the driving transistor DT and the light-emitting element 120. The first reflective electrode RE1 can be connected to the source electrode SE or the drain electrode DE of the driving transistor DT through a contact hole formed in the overcoating layer 115.

The second reflective electrode RE2 can electrically connect the power line VDD and the light-emitting element 120. The second reflective electrode RE2 can be connected to the power line VDD through a contact hole formed in the overcoating layer 115 and electrically connected to a second electrode 125 of the light-emitting element 120 through a second connection electrode CE2 to be described below.

The conductive bonding layer 116 can be disposed on the plurality of reflective electrodes RE and fix the light-emitting element 120 disposed on the conductive bonding layer 116. In addition, the conductive bonding layer 116 can electrically connect the plurality of reflective electrodes RE and the plurality of light-emitting elements 120. Specifically, the conductive bonding layer 116 can fix and electrically connect the first reflective electrode RE1, which is disposed below the conductive bonding layer 116, and a first electrode 124 of the light-emitting element 120 disposed above the conductive bonding layer 116. The conductive bonding layer 116 can be made of a conductive bonding material. For example, the conductive bonding layer 116 can be made of a eutectic bonding material or an anisotropic conductive film (ACF) including conductive balls. However, the present disclosure is not limited thereto.

The plurality of light-emitting elements 120 is provided on the conductive bonding layer 116 and disposed in each of the plurality of subpixels SP. The plurality of light-emitting elements 120 can be elements configured to emit light by using an electric current and include the light-emitting element 120 configured to emit blue light. For example, the plurality of light-emitting elements 120 can each be a light-emitting diode (LED) or a micro LED. However, the present disclosure is not limited thereto.

The light-emitting element 120 includes a first semiconductor layer 121, a light-emitting layer 122, a second semiconductor layer 123, the first electrode 124, and the second electrode 125.

The first semiconductor layer 121 is disposed on the conductive bonding layer 116, and the second semiconductor layer 123 is disposed on the first semiconductor layer 121. The first semiconductor layer 121 and the second semiconductor layer 123 can each be a layer formed by doping a particular material with n-type and p-type impurities. For example, the first semiconductor layer 121 and the second semiconductor layer 123 can each be a layer formed by doping a material, such as gallium nitride (GaN), indium aluminum phosphide (InAlP), or gallium arsenic (GaAs) with n-type and p-type impurities. Further, the p-type impurity can be magnesium, zinc (Zn), beryllium (Be), or the like. The n-type impurity can be silicon (Si), germanium, tin (Sn), or the like. However, the present disclosure is not limited thereto.

The light-emitting layer 122 is disposed between the first semiconductor layer 121 and the second semiconductor layer 123. The light-emitting layer 122 can emit light by receiving positive holes and electrons from the first semiconductor layer 121 and the second semiconductor layer 123.

The light-emitting layer 122 can be configured as a single layer or a multi-quantum well (MQW) structure. For example, the light-emitting layer 122 can be made of indium gallium nitride (InGaN), gallium nitride (GaN), or the like. However, the present disclosure is not limited thereto.

The first electrode 124 is disposed between the first semiconductor layer 121 and the conductive bonding layer 116. The first electrode 124 is an electrode that electrically connects the driving transistor DT and the first semiconductor layer 121. In this case, the first semiconductor layer 121 can be a semiconductor layer doped with n-type impurities, and the first electrode 124 can be a cathode. The first electrode 124 can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 125 is disposed on the second semiconductor layer 123. The second electrode 125 can be disposed on a top surface of the second semiconductor layer 123. The second electrode 125 is an electrode for electrically connecting the power line VDD and the second semiconductor layer 123. In this case, the second semiconductor layer 123 can be a semiconductor layer doped with p-type impurities, and the second electrode 125 can be an anode. The second electrode 125 can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The first planarization layer 117 and the second planarization layer 118 are disposed on the overcoating layer 115 and the plurality of reflective electrodes RE. The first planarization layer 117 and the second planarization layer 118 can be disposed to surround a part of a side surface of each of the plurality of light-emitting elements 120 and fix and protect each of the plurality of light-emitting elements 120.

The connection electrode CE can be disposed on the second planarization layer 118. The connection electrode CE is an electrode disposed in each of the plurality of subpixels SP and configured to electrically connect the light-emitting element 120 and the power line VDD. The connection electrode CE can be connected to the second reflective electrode RE2 through contact holes formed in the first planarization layer 117 and the second planarization layer 118. Therefore, the connection electrode CE can be electrically connected to the power line VDD through the second reflective electrode RE2. Specifically, the connection electrode CE can be disposed on the second planarization layer 118 and connected to the second electrode 125 of the light-emitting element 120.

The third planarization layer 131 is disposed on the light-emitting element 120. The third planarization layer 131 can be a layer for planarizing an upper portion of the light-emitting element.

The first planarization layer 117, the second planarization layer 118, and the third planarization layer 131 can each be made of an organic material. For example, the first planarization layer 117, the second planarization layer 118, and the third planarization layer 131 can each be made of an acrylic-based organic material. However, the present disclosure is not limited thereto.

The bonding layer 132 is disposed on the third planarization layer 131. The bonding layer 132 is a layer for bonding the first substrate 110 and the second substrate 150. Specifically, the bonding layer 132 can be used to bond the first substrate 110, which is formed to the third planarization layer 131, and the second substrate 150 formed to the encapsulation layer 133, as described below. The bonding layer 132 can be made of a transparent photocurable bonding material. However, the present disclosure is not limited thereto.

The encapsulation layer 133 is disposed on the bonding layer 132. The encapsulation layer 133 protects the light-emitting element 120 from physical impact, moisture, or air that can penetrate into the light-emitting element 120 from the outside. The encapsulation layer 133 can include an inorganic layer. For example, the encapsulation layer 133 can be made of various inorganic materials such as silicon nitride (SiNx), silicon oxide (SiOx), or silicon oxynitride (SiON). However, the present disclosure is not limited thereto.

The banks 134, the plurality of color conversion layers 135, and the first transparent layer 136 are disposed on the encapsulation layer 133.

The banks 134 can be disposed between the plurality of subpixels SP and minimize a degree to which the light emitted from the plurality of subpixels SP propagates to another subpixel SP and a color mixture is caused. The banks 134 can be disposed along boundaries between the plurality of subpixels SP and formed in a mesh shape. For example, the bank 134 can be made of an opaque resin or the like including a black material. However, the present disclosure is not limited thereto.

The plurality of color conversion layers 135 is disposed to fill spaces between the banks 134 in the red subpixel and the green subpixel. The plurality of color conversion layers 135 is disposed between the banks 134 in a red subpixel SPR and a green subpixel SPG among the plurality of subpixels SP. The plurality of color conversion layers 135 can be disposed to fill the spaces between the banks 134 on the plurality of light-emitting elements 120. The light emitted from the plurality of light-emitting elements 120 can propagate to the plurality of color conversion layers 135, and color conversion materials of the plurality of color conversion layers 135 can absorb the light and emit light with another wavelength. The plurality of color conversion layers 135 can include a red color conversion layer and a green color conversion layer, and different color conversion materials can be included in the red color conversion layer and the green color conversion layer.

The red color conversion layer is disposed in the red subpixel SPR among the plurality of subpixels SP. The blue light emitted from the light-emitting element 120 can be converted into the red light while passing through the red color conversion layer. For example, the red color conversion layer can convert light, which has a wavelength of about 400 nm or more and 480 nm or less, into the light having a wavelength of about 600 nm or more and 640 nm or less. However, the present disclosure is not limited thereto.

The green color conversion layer is disposed in the green subpixel SPG among the plurality of subpixels SP. The blue light emitted from the light-emitting element 120 can be converted into green light while passing through the green color conversion layer. For example, the green color conversion layer can convert light, which has a wavelength of about 400 nm or more and 480 nm or less, into light having a wavelength of about 520 nm or more and 580 nm or less. However, the present disclosure is not limited thereto.

The first transparent layer 136 can be disposed on the light-emitting element 120 while corresponding to the color conversion layer 135 in a blue subpixel SPB among the plurality of subpixels SP. A side surface of the first transparent layer 136 can adjoin a side surface of the bank 134. Because the light emitted from the light-emitting element 120 is blue light, the color conversion layer is not disposed in the blue subpixel SPB, but the first transparent layer 136, which transmits blue light, is disposed in the blue subpixel SPB, such that the blue light from the light-emitting element 120 can propagate to the upper portion of the second substrate 150 in an intact manner. The first transparent layer 136 can be made of a transparent resin. However, the present disclosure is not limited thereto.

The second substrate 150 is disposed on the bank 134, the color conversion layer 135, and the first transparent layer 136. The second substrate 150 is a substrate that supports various constituent elements disposed below the second substrate 150. Specifically, the second substrate 150 can support the plurality of color filters CFG and CFR, the transmittance adjustment layer 140, the plurality of color conversion layers 135, the bank 134, and the like disposed below the second substrate 150. The second substrate 150 can be made of the same material as the first substrate 110. For example, the second substrate 150 can be made of glass, resin, or the like.

The plurality of color filters CFG and CFR, the transmittance adjustment layer 140, and the second transparent layer 139 are disposed below the second substrate 150.

The plurality of color filters CFG and CFR is disposed below the second substrate 150 in the red subpixel and the green subpixel. In addition, the plurality of color filters CFG and CFR can be disposed to adjoin a side surface of a first transmittance adjustment layer 141 among the transmittance adjustment layers. A width of a cross-section of each of the plurality of color filters CFG and CFR can increase as the distance from the second substrate 150 increases.

The plurality of color filters CFG and CFR can filter light beams with different colors. The green color filter CFG disposed in the green subpixel can transmit green light while filtering out light other than the green light. The red color filter CFR disposed in the red subpixel can transmit the red light while filtering out light other than the red light.

The second transparent layer 139 is disposed below the second substrate 150 in the blue subpixel. The second transparent layer 139 is disposed on the first transparent layer 136 while corresponding to the plurality of color filters CFG and CFR. A side surface of the second transparent layer 139 can adjoin a side surface of the second transmittance adjustment layer 143. Because the light emitted from the light-emitting element 120 is blue light, the second transparent layer 139, which transmits blue light, is disposed in the blue subpixel SPB, instead of a color filter, such that the blue light from the light-emitting element 120 can propagate to the upper portion of the second substrate 150 in an intact manner. The second transparent layer 139 can be made of the same transparent resin as the first transparent layer 136. However, the present disclosure is not limited thereto.

The transmittance adjustment layer 140 is provided below the second substrate 150 and disposed between the plurality of color filters CFG and CFR and the second transparent layer 139. The transmittance adjustment layer 140 includes the first transmittance adjustment layer 141 and the second transmittance adjustment layer 143.

The first transmittance adjustment layer 141 can be disposed below the second substrate 150 and configured to surround the plurality of color filters CFG and CFR. The first transmittance adjustment layer 141 can be disposed in the red subpixel SPR and the green subpixel SPG. Therefore, the first transmittance adjustment layer 141 can adjust transmittances according to viewing angles of the red light and the green light emitted from the red subpixel SPR and the green subpixel SPG among the plurality of subpixels SP.

The first transmittance adjustment layer 141 can include a first layer 141a disposed below the second substrate 150, and a second layer 141b disposed below the first layer 141a of the first transmittance adjustment layer 141.

The first layers 141a of the first transmittance adjustment layers 141 can be disposed to be in contact with the side surfaces of the plurality of color filters CFG and CFR. An end of a top surface of the first layer 141a of the first transmittance adjustment layer 141 can be disposed at a position corresponding to an inclination angle θ1 of 45 degrees from a center of the corresponding one of the plurality of light-emitting elements 120. For example, the end of the top surface of the first layer 141a of the first transmittance adjustment layer 141 can be positioned in an area corresponding to the inclination angle θ1 of 45 degrees from the center of the corresponding one of the plurality of light-emitting elements 120. In addition, in this case, an end of a bottom surface of the first layer 141a of the first transmittance adjustment layer 141 can be positioned in an area corresponding to an inclination angle θ2 of 60 degrees from the center of the corresponding one of the plurality of light-emitting elements 120. In this case, the center of each of the plurality of light-emitting elements 120 can be defined as a center of the light-emitting layer 122 that actually emits light. However, the present disclosure is not limited thereto.

A width of a cross-section of the first layer 141a of the first transmittance adjustment layer 141 can decrease as the distance from the second substrate 150 increases. The side surface of the first layer 141a of the first transmittance adjustment layer 141 can have a surface corresponding to the side surfaces of the plurality of color filters CFG and CFR. The cross-section of the first layer 141a of the first transmittance adjustment layer 141 can have a trapezoidal shape. An area of the bottom surface of the first layer 141a of the first transmittance adjustment layer 141 can be equal to an area of the top surface of the second layer 141b of the first transmittance adjustment layer 141.

A transmittance of the first layer 141a of the first transmittance adjustment layer 141 can be 70%. The first layer 141a of the first transmittance adjustment layer 141 can be made of a semi-transparent material. For example, the first layer 141a of the first transmittance adjustment layer 141 can include any one of polyimide, styrene, methyl methacrylate, polytetrafluoroethylene, benzocyclobutene series resin, and acrylate or a mixture of one or more of the above-mentioned materials. However, the present disclosure is not limited thereto.

A cross-section of the second layer 141b of the first transmittance adjustment layer 141 can have a rectangular shape. The widths of cross-sections of the top and bottom surfaces of the second layer 141b of the first transmittance adjustment layer 141 can be equal to each other. An area of the top surface of the second layer 141b of the first transmittance adjustment layer 141 can be equal to an area of the bottom surface of the first layer 141a of the first transmittance adjustment layer 141. However, the present disclosure is not limited thereto. Like the first layer 141a of the first transmittance adjustment layer 141, the second layer 141b of the first transmittance adjustment layer 141 can also have a trapezoidal shape.

The second layer 141b of the first transmittance adjustment layer 141 can have a lower transmittance than the first layer 141a of the first transmittance adjustment layer 141. The second layer 141b of the first transmittance adjustment layer 141 can include a black material that absorbs light without transmitting light. The black material can include an organic material or an inorganic material. The black material can include a carbon-based material, metal oxide (metal oxide), or the like. However, the present disclosure is not limited thereto.

The second transmittance adjustment layer 143 can be disposed below the second substrate 150 and surround the second transparent layer 139. The second transmittance adjustment layer can be disposed in the blue subpixel. Therefore, the second transmittance adjustment layer 143 can adjust the transmittance of the blue light emitted from the blue subpixel SPB among the plurality of subpixels SP.

The second transmittance adjustment layer 143 can include a first layer 143a disposed below the second substrate 150, and a second layer 143b disposed below the first layer 143a of the second transmittance adjustment layer 143.

The first layer 143a of the second transmittance adjustment layer 143 can be disposed to be in contact with the side surface of the second transparent layer 139. An end of a top surface of the first layer 143a of the second transmittance adjustment layer 143 can be disposed at a position corresponding to an inclination angle θ3 of 60 degrees from the center of the light-emitting element 120. For example, the end of the top surface of the first layer 143a of the second transmittance adjustment layer 143 can be positioned at a position corresponding to an area corresponding to the inclination angle θ3 of 60 degrees from the center of the light-emitting element 120 of the blue subpixel.

A width of a cross-section of the first layer 143a of the second transmittance adjustment layer 143 can decrease as the distance from the second substrate 150 increases. The side surface of the first layer 143a of the second transmittance adjustment layer 143 can have an inclined surface corresponding to the side surface of the second transparent layer 139. The cross-section of the first layer 143a of the second transmittance adjustment layer 143 can have a trapezoidal shape. An area of the bottom surface of the first layer 143a of the second transmittance adjustment layer 143 can be equal to an area of the top surface of the second layer 143b of the second transmittance adjustment layer 143.

A transmittance of the first layer 143a of the second transmittance adjustment layer 143 can be 70%. The first layer 143a of the second transmittance adjustment layer 143 can be made of a semi-transparent material. For example, the first layer 143a of the second transmittance adjustment layer 143 can include any one of polyimide, styrene, methyl methacrylate, polytetrafluoroethylene, benzocyclobutene series resin, and acrylate or a mixture of one or more of the above-mentioned materials. However, the present disclosure is not limited thereto.

A cross-section of the second layer 143b of the second transmittance adjustment layer 143 can have a rectangular shape. The widths of cross-sections of the top and bottom surfaces of the second layer 143b of the second transmittance adjustment layer 143 can be equal to each other. An area of the top surface of the second layer 143b of the second transmittance adjustment layer 143 can be equal to an area of the bottom surface of the first layer 143a of the second transmittance adjustment layer 143. However, the present disclosure is not limited thereto. Like the first layer 143a of the second transmittance adjustment layer 143, the second layer 143b of the second transmittance adjustment layer 143 can also have a trapezoidal shape.

The second layer 143b of the second transmittance adjustment layer 143 can have a lower transmittance than the first layer 143a of the second transmittance adjustment layer 143. The second layer 143b of the second transmittance adjustment layer 143 can include a black material that absorbs light without transmitting light. The black material can include an organic material or an inorganic material. The black material can include a carbon-based material, metal oxide (metal oxide), or the like. However, the present disclosure is not limited thereto.

Meanwhile, the second transmittance adjustment layer 143 can include a black material. For example, both the first layer 143a and the second layer 143b of the second transmittance adjustment layer 143 can include a black material. In this case, the first layer 143a and the second layer 143b can be configured as a single layer or separate layers.

A fourth planarization layer 137 is disposed below the plurality of color filters CFG and CFR, the second transparent layer 139, and the transmittance adjustment layer 140. The fourth planarization layer 137 is a layer for planarizing lower portions of the plurality of color filters CFG and CFR, a lower portion of the second transparent layer 139, and a lower portion of the transmittance adjustment layer 140. The fourth planarization layer 137 can be made of an organic material. For example, the fourth planarization layer 137 can be made of an acrylic-based organic material. However, the present disclosure is not limited thereto.

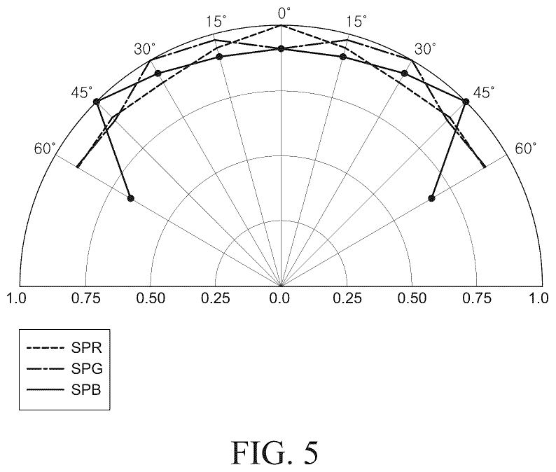

Hereinafter, an effect of the display device according to the embodiment of the present disclosure will be described with reference to FIG. 5.

FIG. 5 is a graph illustrating viewing angles for respective subpixels of the display device according to a comparative example. In this case, the display device according to the comparative example means a case in which the transmittance adjustment layer of the display device according to the embodiment of the present disclosure is not used. The graph in FIG. 5 shows a change in luminance with respect to a change in viewing angle on the basis that a viewing angle in a front view is 0 degrees. In this case, the luminance value is expressed as a relative ratio on the basis that a maximum luminance value is 1.0.

In the display device according to the comparative example, the light emitted from the blue light-emitting element in the green subpixel SPG and the red subpixel SPR passes through the color conversion layer and is discharged to the outside, whereas the light emitted from the blue light-emitting element in the blue subpixel SPB is discharged to the outside in an intact manner without passing through the color conversion layer. In this case, in the green subpixel SPG and the red subpixel SPR, the light emitted from the blue light-emitting element is scattered by the color conversion materials of the color conversion layer, which improves viewing angle characteristics. However, in the blue subpixel SPB, the light emitted from the blue light-emitting element is discharged to the outside in an intact manner without passing through the color conversion layer, which can relatively degrade the viewing angle characteristics. Therefore, with reference to FIG. 5, in the green subpixel SPG and the red subpixel SPR, a luminance value is about 85 to 90% based on maximum luminance even though the viewing angle is larger than 45 degrees. However, in case that the viewing angle is larger than 45 degrees in the blue subpixel SPB, the luminance rapidly decreases, such that a luminance value is about 60% based on the maximum luminance in case that the viewing angle is 60 degrees.

As described above, the configuration in which a scattering layer and a color filter are also disposed in the blue subpixel SPB can be considered to suppress deteriorations in luminance viewing angles and color properties in the blue subpixel SPB. In case that the scattering layer and the color filter are disposed in the blue subpixel SPB as described above, viewing angle characteristics can be improved, but the luminous efficiency in the blue subpixel SPB can be greatly decreased.

Therefore, in the display device 100 according to the embodiment of the present disclosure, the transmittance adjustment layer 140 can be disposed to improve the color properties. Specifically, in the display device 100 according to the embodiment of the present disclosure, the first transmittance adjustment layer 141 is disposed to surround the plurality of color filters CFG and CFR in the red subpixel SPR and the green subpixel SPG among the plurality of subpixels SP. In this case, the transmittance in a viewing angle area of 45 to 60 degrees can be decreased to 70% when the light is allowed to pass through the first layer 141a of the first transmittance adjustment layer 141 by the second layer 141b having a lower transmittance than the first layer 141a of the first transmittance adjustment layer 141 and the first layer 141a of the first transmittance adjustment layer 141. Therefore, it is possible to reduce viewing angle deviations between the red subpixel, the green subpixel, and the blue subpixel. Therefore, in the display device 100 according to the embodiment of the present disclosure, the first transmittance adjustment layer 141 is disposed, which can improve the color properties while reducing the viewing angle deviation.

In addition, in the display device 100 according to the embodiment of the present disclosure, the first transparent layer 136 and the second transparent layer are disposed, which can minimize a deterioration in blue light efficiency. Specifically, in the display device 100 according to the embodiment of the present disclosure, in the blue subpixel SPB among the plurality of subpixels SP, the first transparent layer 136 is disposed instead of the plurality of color conversion layers 135, and the second transparent layer 139 is disposed instead of the plurality of color filters CFR and CFG, such that the blue light emitted from the light-emitting element 120 is discharged in an intact manner, and there can be no light eliminated by the color conversion layer 135. Therefore, in the display device 100 according to the embodiment of the present disclosure, the first transparent layer 136 and the second transparent layer 139 are disposed, which can minimize a deterioration in blue light efficiency.

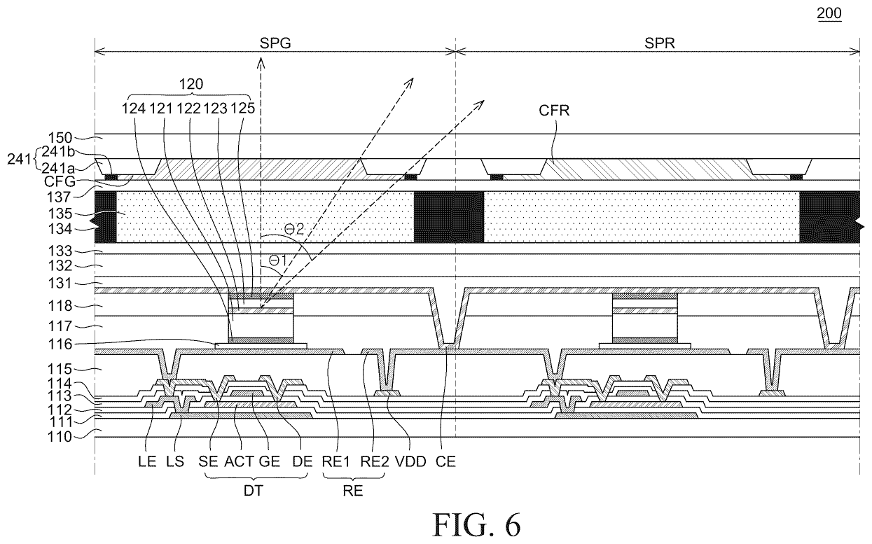

FIG. 6 is an enlarged cross-sectional view illustrating a green subpixel and a red subpixel of a display device according to another embodiment of the present disclosure. A display device 200 in FIG. 6 is substantially identical in configuration to the display device 100 in FIGS. 1 to 4, except for the plurality of color filters CFG and CFR and a first transmittance adjustment layer 241. Therefore, repeated descriptions of the identical components will be omitted or may be briefly provided.

With reference to FIG. 6, in the green subpixel SPG and the red subpixel SPR among the plurality of subpixels SP, the first transmittance adjustment layer 241 can be disposed below the second substrate 150 and surround the plurality of color filters CFG and CFR. A part of a first transmittance adjustment layer 241 can be disposed to overlap the plurality of color filters CFG and CFR. Therefore, one side edge of the first transmittance adjustment layer 241 can be covered by the plurality of color filters CFG and CFR.

The first transmittance adjustment layer 241 can include a first layer 241a disposed below the second substrate 150, and a second layer 241b disposed below the first layer 241a of the first transmittance adjustment layer 241.

A bottom surface and a side surface of the first layer 241a of the first transmittance adjustment layer 241 can be disposed to partially adjoin the side surfaces of the plurality of color filters CFG and CFR. An end of a top surface of the first layer 241a of the first transmittance adjustment layer 241 can be disposed at a position corresponding to the inclination angle θ1 of 45 degrees from the center of the corresponding one of the plurality of light-emitting elements 120. For example, the end of the top surface of the first layer 241a of the first transmittance adjustment layer 241 can be positioned in an area corresponding to the inclination angle θ1 of 45 degrees from the center of the corresponding one of the plurality of light-emitting elements 120.

A cross-section of the first layer 241a of the first transmittance adjustment layer 241 can have a trapezoidal shape. An area of the bottom surface of the first layer 241a of the first transmittance adjustment layer 241 can be larger than an area of the top surface of the second layer 241b of the first transmittance adjustment layer 241.

A transmittance of the first layer 241a of the first transmittance adjustment layer 241 can be 70%. The first layer 241a of the first transmittance adjustment layer 241 can be made of a semi-transparent material. For example, the first layer 241a of the first transmittance adjustment layer 241 can include any one of polyimide, styrene, methyl methacrylate, polytetrafluoroethylene, benzocyclobutene series resin, and acrylate or a mixture of one or more of the above-mentioned materials.

The second layer 241b of the first transmittance adjustment layer 241 can be disposed to be close to one side of the end of the bottom surface of the first layer 241a of the first transmittance adjustment layer 241. The end of the top surface of the second layer 241b of the first transmittance adjustment layer 241 can be positioned in an area corresponding to the inclination angle θ2 of 60 degrees from the center of the corresponding one of the plurality of light-emitting elements 120.

A cross-section of the second layer 241b of the first transmittance adjustment layer 241 can have a rectangular shape. The widths of cross-sections of the top and bottom surfaces of the second layer 241b of the first transmittance adjustment layer 241 can be equal to each other. However, the present disclosure is not limited thereto. Like the first layer 241a of the first transmittance adjustment layer 241, the second layer 241b of the first transmittance adjustment layer 241 can also have a trapezoidal shape. The second layer 241b of the first transmittance adjustment layer 241 can have a lower transmittance than the first layer 241a of the first transmittance adjustment layer 241. The second layer 241b of the first transmittance adjustment layer 241 can include a black material that absorbs light without transmitting light. The black material can include an organic material or an inorganic material. The black material can include a carbon-based material, metal oxide (metal oxide), or the like. However, the present disclosure is not limited thereto.

Therefore, in the display device 200 according to another embodiment of the present disclosure, the first transmittance adjustment layer 241 is disposed to surround the plurality of color filters CFG and CFR in the red subpixel SPR and the green subpixel SPG among the plurality of subpixels SP. In this case, the transmittance in a viewing angle area of 45 to 60 degrees can be decreased to 70% when the light is allowed to pass through the first layer 241a of the first transmittance adjustment layer 241 by the second layer 241b having a lower transmittance than the first layer 241a of the first transmittance adjustment layer 241 and the first layer 241a of the first transmittance adjustment layer 241. As such, it is possible to reduce viewing angle deviations between the red subpixel, the green subpixel, and the blue subpixel. Accordingly, in the display device 200 according to the embodiment of the present disclosure, the first transmittance adjustment layer 241 is disposed, which can improve the color properties while reducing the viewing angle deviation.

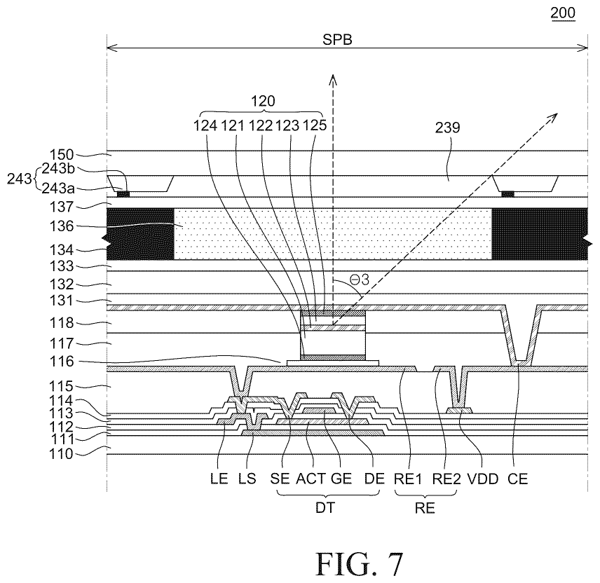

FIG. 7 is an enlarged cross-sectional view illustrating a blue subpixel of the display device according to another embodiment of the present disclosure. The display device 200 in FIG. 7 is substantially identical in configuration to the display device 100 in FIGS. 1 to 4, except for a second transparent layer 239 and a second transmittance adjustment layer 243. Therefore, repeated descriptions of the identical components will be omitted or may be briefly provided.

With reference to FIG. 7, in the blue subpixel SPB among the plurality of subpixels SP, the second transmittance adjustment layer 243 can be disposed below the second substrate 150 and surround the second transparent layer 239. A part of the second transmittance adjustment layer 243 can be disposed to overlap the second transparent layer 239. Therefore, one side edge of the second transmittance adjustment layer 243 can be covered by the second transparent layer 239.

The second transmittance adjustment layer 243 can include a first layer 243a disposed below the second substrate 150, and a second layer 243b disposed below the first layer 243a of the second transmittance adjustment layer 243.

The bottom and side surfaces of the first layer 243a of the second transmittance adjustment layer 243 can be disposed to partially adjoin a side surface of the second transparent layer 239. The end of the top surface of the first layer 243a of the second transmittance adjustment layer 243 can be disposed at a position corresponding to the inclination angle θ3 of 60 degrees from the center of the light-emitting element 120. For example, the end of the top surface of the first layer 243a of the second transmittance adjustment layer 243 can be positioned at a position corresponding to an area corresponding to the inclination angle θ3 of 60 degrees from the center of the light-emitting element 120 of the blue subpixel.

The cross-section of the first layer 243a of the second transmittance adjustment layer 243 can have a trapezoidal shape. An area of the bottom surface of the first layer 243a of the second transmittance adjustment layer 243 can be larger than an area of the top surface of the second layer 243b of the second transmittance adjustment layer 243.

A transmittance of the first layer 243a of the second transmittance adjustment layer 243 can be 70%. The first layer 243a of the second transmittance adjustment layer 243 can be made of a semi-transparent material. For example, the first layer 243a of the second transmittance adjustment layer 243 can include any one of polyimide, styrene, methyl methacrylate, polytetrafluoroethylene, benzocyclobutene series resin, and acrylate or a mixture of one or more of the above-mentioned materials. However, the present disclosure is not limited thereto.

The second layer 243b of the second transmittance adjustment layer 243 can be disposed to be close to one side of the end of the bottom surface of the first layer 243a of the second transmittance adjustment layer 243. A cross-section of the second layer 243b of the second transmittance adjustment layer 243 can have a rectangular shape. The widths of cross-sections of the top and bottom surfaces of the second layer 243b of the second transmittance adjustment layer 243 can be equal to each other. The present disclosure is not limited thereto. Like the first layer 243a of the second transmittance adjustment layer 243, the second layer 243b of the second transmittance adjustment layer 243 can also have a trapezoidal shape.

The second layer 243b of the second transmittance adjustment layer 243 can have a lower transmittance than the first layer 243a of the second transmittance adjustment layer 243. The second layer 243b of the second transmittance adjustment layer 243 can include a black material that absorbs light without transmitting light. The black material can include an organic material or an inorganic material. The black material can include a carbon-based material, metal oxide (metal oxide), or the like. However, the present disclosure is not limited thereto.

Meanwhile, the second transmittance adjustment layer 243 can include a black material. Both the first layer 243a and the second layer 243b of the second transmittance adjustment layer 243 can include a black material. In this case, the first layer 243a and the second layer 243b can be configured as a single layer or separate layers.

Therefore, in the display device 200 according to another embodiment of the present disclosure, the second transmittance adjustment layer 243 is disposed to surround the second transparent layer 239 in the blue subpixel SPB among the plurality of subpixels SP. In this case, the transmittance at a viewing angle of 60 degrees can be decreased to 70% when the light is allowed to pass through the first layer 243a of the second transmittance adjustment layer 243 by the second layer 243b having a lower transmittance than the first layer 243a of the second transmittance adjustment layer 243 and the first layer 243a of the second transmittance adjustment layer 243. Therefore, it is possible to reduce viewing angle deviations between the red subpixel, the green subpixel, and the blue subpixel. As such, in the display device 200 according to another embodiment of the present disclosure, the second transmittance adjustment layer 243 is disposed, which can improve the color properties while reducing the viewing angle deviation.

In addition, in the display device 200 according to another embodiment of the present disclosure, in the blue subpixel SPB among the plurality of subpixels SP, the first transparent layer 136 is disposed instead of the plurality of color conversion layers 135, and the second transparent layer 239 is disposed instead of the plurality of color filters CFR and CFG, such that the blue light emitted from the light-emitting element 120 is discharged in an intact manner, and there can be no light eliminated by the color conversion layer 135. Therefore, in the display device 200 according to another embodiment of the present disclosure, the first transparent layer 136 and the second transparent layer 239 are disposed, which can minimize a deterioration in blue light efficiency.

The example embodiments of the present disclosure can also be described as follows:

According to an aspect of the present disclosure, a display device includes a first substrate on which a plurality of subpixels is defined, a plurality of blue light-emitting elements respectively disposed on the plurality of subpixels, a plurality of color conversion layers disposed on the plurality of blue light-emitting elements in a red subpixel and a green subpixel among the plurality of subpixels, a plurality of color filters disposed on the plurality of color conversion layers in the red subpixel and the green subpixel, a second substrate disposed on the plurality of color filters, and a first transmittance adjustment layer disposed below the second substrate and configured to surround the plurality of color filters, the first transmittance adjustment layer includes a first layer disposed below the second substrate, and a second layer disposed below the first layer of the first transmittance adjustment layer and having a lower transmittance than the first layer of the first transmittance adjustment layer.

A width of a cross-section of the first layer of the first transmittance adjustment layer can decrease as the distance of the cross-section from the second substrate increases.

An area of a bottom surface of the first layer of the first transmittance adjustment layer can be equal to an area of a top surface of the second layer of the first transmittance adjustment layer.

An area of a bottom surface of the first layer of the first transmittance adjustment layer can be larger than an area of a top surface of the second layer of the first transmittance adjustment layer, and the second layer of the first transmittance adjustment layer can be disposed to be close to one side of an end of the bottom surface of the first layer of the first transmittance adjustment layer.

A transmittance of the first layer of the first transmittance adjustment layer can be 70%.

An end of a top surface of the first layer of the first transmittance adjustment layer can be positioned at a position corresponding to an inclination angle of 45 degrees from a center of the corresponding one of the plurality of blue light-emitting elements, the center of the blue light-emitting element can be the center of a light-emitting layer of the blue light-emitting element, the inclination angle of 45 degrees is an inclination angle of a vertex being the center, formed with a normal that passes through the center perpendicularly to the light-emitting layer.

The second layer of the first transmittance adjustment layer can include a black material.

An end of a top surface of the second layer of the first transmittance adjustment layer can be disposed at a position corresponding to an inclination angle of 60 degrees from a center of the corresponding one of the plurality of blue light-emitting elements, the center of the blue light-emitting element can be the center of a light-emitting layer of the blue light-emitting element, the inclination angle of 60 degrees is an inclination angle of a vertex being the center, formed with a normal that passes through the center perpendicularly to the light-emitting layer.

The display device can further include a first transparent layer disposed, in a blue subpixel among the plurality of subpixels, on the plurality of blue light-emitting elements while corresponding to the color conversion layer, and a second transparent layer disposed, in the blue subpixel, on the first transparent layer while corresponding to the plurality of color filters. The display device can further include a second transmittance adjustment layer disposed below the second substrate while corresponding to the first transmittance adjustment layer, configured to surround the second transparent layer.

The second transmittance adjustment layer can include a first layer disposed below the second substrate, and a second layer disposed below the first layer of the second transmittance adjustment layer and can have a lower transmittance than the first layer of the second transmittance adjustment layer.

An end of a top surface of the first layer of the second transmittance adjustment layer can be disposed at a position corresponding to an inclination angle of 60 degrees from a center of the corresponding one of the plurality of blue light-emitting elements, the center of the blue light-emitting element can be the center of a light-emitting layer of the blue light-emitting element, the inclination angle of 60 degrees is an inclination angle of a vertex being the center, formed with a normal that passes through the center perpendicularly to the light-emitting layer.

A transmittance of the first layer of the second transmittance adjustment layer can be 70%, and the second layer of the second transmittance adjustment layer can include a black material.

The second transmittance adjustment layer can include a black material.

An area of a bottom surface of the first layer of the second transmittance adjustment layer can be larger than an area of a top surface of the second layer of the second transmittance adjustment layer, and the second layer of the second transmittance adjustment layer can be disposed to be close to one side of an end of the bottom surface of the first layer of the second transmittance adjustment layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a first substrate on which a plurality of subpixels is defined, the plurality of subpixels including a red subpixel and a green subpixel;
a plurality of blue light-emitting elements respectively disposed on the plurality of subpixels;
a plurality of color conversion layers disposed on the plurality of blue light-emitting elements in the red subpixel and the green subpixel;
a plurality of color filters disposed on the plurality of color conversion layers in the red subpixel and the green subpixel;
a second substrate disposed on the plurality of color filters; and
a first transmittance adjustment layer disposed below the second substrate and configured to surround the plurality of color filters,
wherein the first transmittance adjustment layer comprises:
a first layer disposed below the second substrate; and
a second layer disposed below the first layer of the first transmittance adjustment layer, and having a lower transmittance than the first layer of the first transmittance adjustment layer.

2. The display device of claim 1, wherein a width of a cross-section of the first layer of the first transmittance adjustment layer decreases as a distance of the cross-section from the second substrate increases.

3. The display device of claim 2, wherein an area of a bottom surface of the first layer of the first transmittance adjustment layer is equal to an area of a top surface of the second layer of the first transmittance adjustment layer.

4. The display device of claim 2, wherein an area of a bottom surface of the first layer of the first transmittance adjustment layer is larger than an area of a top surface of the second layer of the first transmittance adjustment layer, and
wherein the second layer of the first transmittance adjustment layer is disposed to be close to one side of an end of the bottom surface of the first layer of the first transmittance adjustment layer.

5. The display device of claim 1, wherein a transmittance of the first layer of the first transmittance adjustment layer is 70%.

6. The display device of claim 5, wherein an end of a top surface of the first layer of the first transmittance adjustment layer is positioned at a position corresponding to an inclination angle of 45 degrees from a center of the corresponding one of the plurality of blue light-emitting elements,
the center of the blue light-emitting element is the center of a light-emitting layer of the blue light-emitting element, and
the inclination angle of 45 degrees is an inclination angle of a vertex being the center, formed with a normal that passes through the center perpendicularly to the light-emitting layer of the blue light-emitting element.

7. The display device of claim 1, wherein the second layer of the first transmittance adjustment layer includes a black material.

8. The display device of claim 7, wherein an end of a top surface of the second layer of the first transmittance adjustment layer is disposed at a position corresponding to an inclination angle of 60 degrees from a center of the corresponding one of the plurality of blue light-emitting elements,
the center of the blue light-emitting element is the center of a light-emitting layer of the blue light-emitting element, and
the inclination angle of 60 degrees is an inclination angle of a vertex being the center, formed with a normal that passes through the center perpendicularly to the light-emitting layer of the blue light-emitting element.

9. The display device of claim 1, further comprising:
a first transparent layer disposed, in a blue subpixel among the plurality of subpixels, on the plurality of blue light-emitting elements while corresponding to the color conversion layer; and
a second transparent layer disposed, in the blue subpixel, on the first transparent layer while corresponding to the plurality of color filters.

10. The display device of claim 9, further comprising:
a second transmittance adjustment layer disposed below the second substrate while corresponding to the first transmittance adjustment layer, the second transmittance adjustment layer being configured to surround the second transparent layer.

11. The display device of claim 10, wherein the second transmittance adjustment layer comprises:
a first layer disposed below the second substrate; and
a second layer disposed below the first layer of the second transmittance adjustment layer and having a lower transmittance than the first layer of the second transmittance adjustment layer.

12. The display device of claim 11, wherein an end of a top surface of the first layer of the second transmittance adjustment layer is disposed at a position corresponding to an inclination angle of 60 degrees from a center of the corresponding one of the plurality of blue light-emitting elements,
the center of the blue light-emitting element is the center of a light-emitting layer of the blue light-emitting element, and
the inclination angle of 60 degrees is an inclination angle of a vertex being the center, formed with a normal that passes through the center perpendicularly to the light-emitting layer of the blue light-emitting element.

13. The display device of claim 11, wherein a transmittance of the first layer of the second transmittance adjustment layer is 70%, and the second layer of the second transmittance adjustment layer includes a black material.

14. The display device of claim 10, wherein the second transmittance adjustment layer includes a black material.

15. The display device of claim 11, wherein an area of a bottom surface of the first layer of the second transmittance adjustment layer is larger than an area of a top surface of the second layer of the second transmittance adjustment layer, and
wherein the second layer of the second transmittance adjustment layer is disposed to be close to one side of an end of the bottom surface of the first layer of the second transmittance adjustment layer.
